(19) United States
(12) Patent Application Publication
(10) Pub. No.: US 2026/0225455 A1
(43) Pub. Date: Aug. 6, 2026

(54) METHOD, CONTROLLER AND SYSTEM FOR HANDLING ISOLATION FAULTS IN BATTERY OPERATED SYSTEM

(71) Applicant: Scania CV AB, Södertälje (SE)

(72) Inventors: Sanju KANAYATHIL RAJU, Södertälje (SE); Björn BÖKELUND, Älvsjö (SE); Mathias BJÖRKMAN, Tullinge (SE); Niklas PETTERSSON, Stockholm (SE)

(73) Assignee: Scania CV AB, Södertälje (SE)

(21) Appl. No.: 19/146,304

(22) PCT Filed: Jan. 15, 2024
(86) PCT No.: PCT/SE2024/050028

§ 371 Date: Jul. 8, 2025

(30) Foreign Application Priority Data
Jan. 19, 2023 (SE) 2350041-6

(51) Int. Cl. B60L 3/00; B60L 58/18; G01R 31/00; G01R 31/364

(52) U.S. Cl. CPC B60L 3/0069; B60L 3/0046; B60L 58/18; G01R 31/007; G01R 31/364; B60L 2250/16

(57) ABSTRACT

The present application relates to a method of handling isolation faults in a battery operated high voltage electric system for propelling a vehicle, the system comprising a plurality of propulsion battery packs and at least one electric machine connected to said plurality of propulsion battery packs, the method comprising performing isolation measurement of the system when in operation, if an isolation fault is detected in the system, then disconnecting all propulsion battery packs; measuring isolation resistance between a plus side of each battery pack and ground and measuring isolation resistance between a minus side of each battery pack and ground; if the measured resistance in a battery pack is above a pre-determined value, re-connecting that battery pack, and if the measured resistance is below a pre-determined value in a battery pack, maintaining that battery pack disconnected.

### TECHNICAL AREA

The present application relates to isolation faults that may occur in battery operated systems such as electrically propelled vehicles and how such faults may be handled.

### BACKGROUND OF INVENTION

There is a rapid development of vehicles operated and propelled by electricity, either as hybrid vehicles with electrical machines and combustion engines or as completely electrically propelled vehicles. For larger and heavier electrically propelled vehicles such as trucks and busses, most often several battery packs are required in order to provide the necessary amount of energy for driving longer distances.

This entails new safety measures in the event that there is a major fault in the high voltage electric system, because of the large amounts of energy in the battery packs and the high voltages used in these systems. One type of major fault that can occur is a vehicle isolation fault during driving, or at least when the battery packs are connected and the high voltage system is in operation.

The monitoring system of the vehicle can detect such an isolation fault and alert a driver of the vehicle that there is a fault in the high voltage electric system. The monitoring system can however not detect where in the electric system the fault is located. The fault may be a vehicle/external fault, for instance a short circuit in the high voltage circuit or be a battery internal fault, for example coolant leakage or short circuit between cells within one battery pack. Since all battery packs are connected to the high voltage electrical system when such an isolation fault occurs, it is not possible to distinguish an internal fault. When such a fault occurs, the system alerts the driver.

In order to detect an internal fault, the vehicle has to be stopped and all battery packs have to be disconnected from the system in order to measure and detect an internal fault in a specific battery pack. This is done by the driver stopping the vehicle and manually switching off the power from the electric system and then switching on again, which triggers a diagnostic test and measurements of the battery packs. If a battery pack is found to have an internal isolation fault, that battery pack is left disconnected while the rest of the battery packs that have been found functional are re-connected, after which the vehicle may be operated again.

This is a drawback in that the driver has to quite quickly find a place to stop, which might be difficult for instance when driving on a motorway, with a risk that a stop might cause traffic problem. Thus, this causes an increased stress on the driver to handle the vehicle such that traffic problems are minimized as well as to avoid possible added faults due to continued driving.

There is thus a need for further measures regarding handling isolation faults in electrically propelled vehicles.

### BRIEF DESCRIPTION OF INVENTION

In the description, the word vehicle is used. In this regard, vehicle is to be understood as any craft that can be moved or propelled by an electrical machine provided with energy from a plurality of battery packs. Thus, cars, trucks, busses, trains, boats, ships etc. are comprised in the word vehicle.

According to one aspect, a method of handling isolation faults in a battery operated high voltage electric system for propelling a vehicle is provided, wherein the method is performed by a controller. The system may comprise a plurality of propulsion battery packs and at least one electric machine connected to the plurality of propulsion battery packs. The method may comprise the steps of performing isolation measurement of the system when in operation. If an isolation fault is detected in the system, then disconnecting all propulsion battery packs, measuring isolation resistance between a plus side of each battery pack and ground and measuring isolation resistance between a minus side of each battery pack and ground, if the measured resistance in a battery pack is above a pre-determined value, re-connecting that battery pack, and if the measured resistance is below a pre-determined value in a battery pack, maintaining that battery pack disconnected.

This has the advantage that the method may be performed during operation of the vehicle, i.e. during driving and the vehicle does not have to be stopped in order to diagnose a major isolation fault. It is of course possible to perform the operation when the vehicle is at a standstill but active or in operation when the isolation fault occurs. The method is thus performed automatically without requiring interaction from a driver.

Preferably, the isolation measurement of the high voltage electric system may be performed periodically when the system is in operation. Thus, any major isolation faults occurring will be detected and handled rapidly. The method may further comprise the step of providing information that at least one battery pack is disconnected from the system, and preferably also to an operator of the vehicle. This provides the driver of the vehicle that something has occurred and has been handled. The pre-determined value may be based on isolation resistance value above around 100 ohms per volt as regarded as safe for operation, as stipulated in the Regulation 100 of UNECE.

Further, a computer program product is provided comprising instructions which, when the program is executed by a computer, cause the computer to carry out the method. Moreover, a computer-readable storage medium is provided comprising instructions which, when executed by a computer, cause the computer to carry out the method.

According to another aspect, a controller for handling isolation faults in a battery operated high voltage electric system is provided for propelling a vehicle, wherein the system may comprise a plurality of propulsion battery packs, each propulsion battery pack provided with contactors, each battery pack provided with means for measuring isolation resistance connected to said controller, and at least one electric machine connected to said plurality of battery packs. If the controller detects an isolation fault in the system, then the contactors are activated for disconnecting all propulsion battery packs. Further, information may be obtained from the isolation resistance measuring means regarding the isolation resistance between a plus side of each battery pack and ground and the isolation resistance between a minus side of each battery pack and ground, and activating the contactors of a battery pack for re-connection to the system if the obtained resistance value in that battery pack is above a pre-determined value, and maintaining a battery pack disconnected from the system if the obtained resistance value in that battery pack is below a pre-determined value.

Further, a high voltage electric system is provided for propelling a vehicle, the system comprising a plurality of propulsion battery packs, each battery pack provided with contactors, each battery pack provided with means for measuring isolation resistance, at least one electric machine connected to the plurality of propulsion battery packs, and a controller.

These and other aspects of, and advantages with, the present invention will become apparent from the following detailed description of the invention and from the accompanying drawings.

### BRIEF DESCRIPTION OF DRAWINGS

In the following detailed description of the invention, reference will be made to the accompanying drawings, of which

FIG. 1 schematically shows an electrically propelled vehicle,

FIG. 2 schematically shows a battery pack connected to a high voltage electric system comprised in a vehicle, and

FIG. 3 is a flow chart of a method for handling isolation faults.

### DETAILED DESCRIPTION OF THE INVENTION

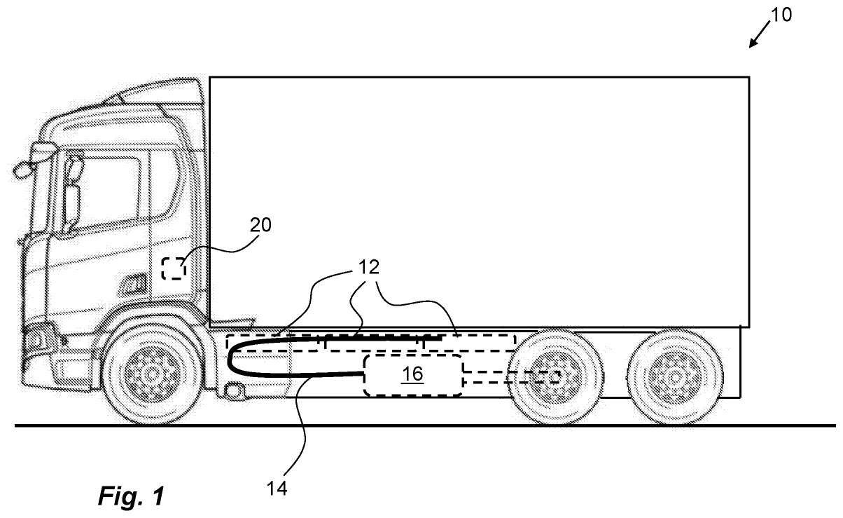

An example of the solution according to the application will be described in connection with the use in a heavy land-based vehicle 10 such as a bus or a truck, FIG. 1.

The vehicle is provided with a plurality of battery packs 12. Each battery pack comprises a plurality of battery cells 13 inter-connected to provide a certain output voltage. The build-up and configuration of battery packs is well-known and will not be described in detail as such. The battery packs are connected to a high voltage electric system 14 comprising electric wiring. To the high voltage electric system, one or several electric machines 16 are connectable for propelling the vehicle. Further consumers may also be connectable to the high voltage electric system 14.

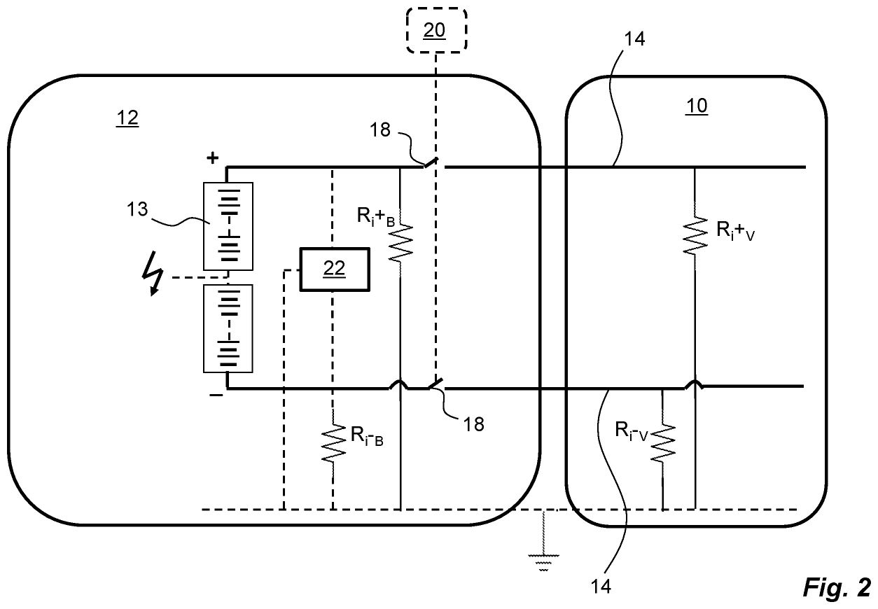

Each battery pack is provided with contactors 18, FIG. 2, for connection and de-connection of each battery pack to the high voltage electric system 14. It is to be understood that in this context, the word contactor may comprise several different solutions that are capable of connecting and disconnecting the battery packs, such as mechanical switches, electronical circuits, power electronic devices or combinations thereof. The contactors 18 can be activated by a controller 20 that is a part of a monitoring and surveillance system for the high voltage electric system 14. In this regard, it is of course possible that contactors are provided externally of the battery packs, which could form a part of connection devices between the battery packs and the wiring of the electrical system. Each battery pack 12 is further provided with different types of sensors and measuring devices for monitoring the status of the battery pack. One such features is a means or a device 22 for measuring the isolation resistance in the battery pack. As seen in FIG. 2, the measuring device 22 is arranged to measure isolation resistance between the plus side of the battery pack and ground, R_{i+B}, as well as the resistance between the minus side of the battery pack and ground R_{i-B}. In this application with a vehicle, the ground may be the chassis of the vehicle.

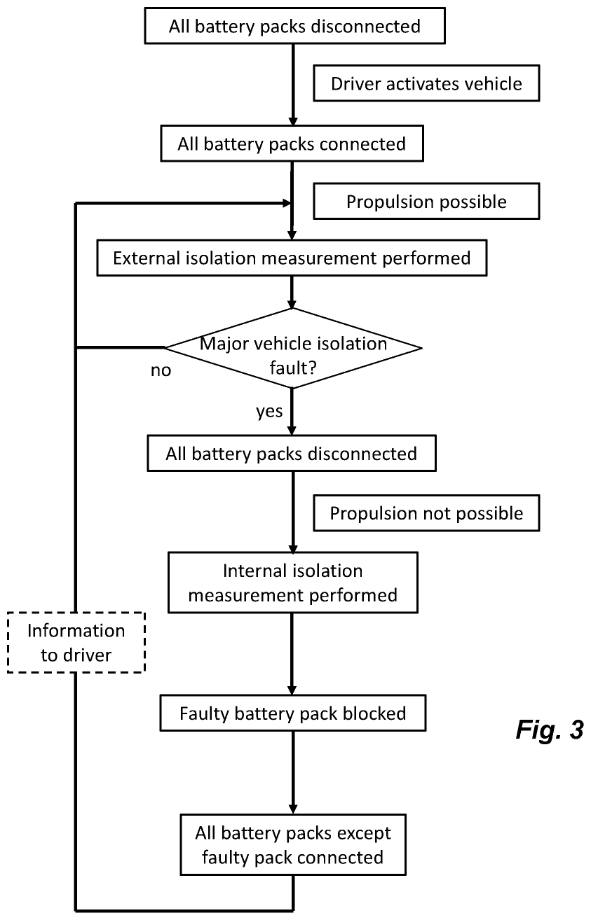

The solution according to the application is intended to function as follows as seen in FIG. 3. When the vehicle is parked and inactivated, all battery packs 12 are disconnected from the high voltage electrical system. When activating the vehicle for operation, the driver operates an appropriate start feature. The controller may perform an initial diagnostic test of the electrical system and the battery packs. The controller then activates the contactors to connect the battery packs to the high voltage electrical system. The vehicle can now be operated and propelled by the electrical machine or machines with power from the battery packs. During operation, the controller continuously/periodically monitors the high voltage electrical system, including measurements of isolation of the electrical system.

If a major isolation fault occurs during operation of the vehicle, this is detected by the controller 20. However, since the measurement is performed on the whole system with all battery packs connected, that is both the isolation resistance of the battery packs R_{iB} as well as the isolation resistance of the high voltage electrical system of the vehicle R_{iV}, it is not possible to obtain information whether the isolation fault is internal, i.e. in one or more of the battery packs, or external, i.e. in the high voltage electrical system.

In order to detect where the isolation fault is located, the controller 20 temporarily disconnects all battery packs via the contactors 18. During the disconnection, isolation resistance measurements are performed on all battery packs. If one or more battery packs each are found to have an isolation resistance below a pre-set value, this indicates that there is a major isolation fault in that or those battery packs.

After the measurement, the controller re-connects the battery packs that have an isolation resistance above the pre-determined value. On the other hand, battery packs that have been found to have an isolation resistance below the pre-determined value are blocked and maintained disconnected. The vehicle can continue the operation, but now with fewer battery packs connected. Since the measurement of the isolation resistance in the battery packs is performed in a short period of time, in the region of 5 seconds, and thus the battery packs are disconnected for a short period of time, it is possible to perform this action while the vehicle is moving, and due to the inertia at higher speeds for a heavy vehicle such as a truck or bus, the velocity of the vehicle will not be affected in any major way during the dis-connection and re-connection operation of the battery packs. This has the advantage that the vehicle does not have to be stopped in order to diagnose a major isolation fault. In this regard, it is of course possible to perform the operation when the vehicle is at a standstill but active or in operation when the isolation fault occurs.

The pre-determined isolation value may depend on several factors and be set depending on the desired level of safe operation. As an indication, Regulation No 100 of UNECE stipulates that an isolation resistance value above around 100 ohms per volt is regarded as safe for operation of the system.

If an isolation fault is detected by the controller, this is preferably indicated in a suitable way to the driver of the vehicle, so that he or she is aware that an isolation fault has occurred, has been handled and that it is possible to continue driving.

However, if one or more battery packs have been disconnected, the driver should preferably be informed that the available power from the batteries has been reduced. It should be understood that the embodiment described above and shown in the drawings is to be regarded only as a non-limiting example of the application and that it may be modified in many ways within the scope of the patent claims.

1. A method of handling isolation faults in a battery operated high voltage electric system for propelling a vehicle, wherein the method is performed by a controller, the system comprising a plurality of propulsion battery packs and at least one electric machine connected to said plurality of propulsion battery packs, the method comprising:
performing isolation measurement of the system when in operation;
if an isolation fault is detected in the system, then disconnecting all propulsion battery packs;
measuring isolation resistance between a plus side of each battery pack and ground and measuring isolation resistance between a minus side of each battery pack and ground; and
if the measured isolation resistance in a battery pack is above a pre-determined value, re-connecting that battery pack, and if the measured isolation resistance is below a pre-determined value in a battery pack, maintaining that battery pack disconnected.

2. A method according to claim 1, wherein the isolation measurement of the high voltage electric system is performed periodically when the system is in operation.

3. A method according to claim 1, further comprising providing information that at least one battery pack is disconnected from the system.

4. A method according to claim 3, wherein the information is provided to an operator of the vehicle.

5. A method according to claim 1, wherein the pre-determined value is based on isolation resistance value above 100 ohms per volt as regarded as safe for operation.

6. A computer program product stored on a non-transitory computer-readable medium, said computer program product for handling isolation faults in a battery operated high voltage electric system for propelling a vehicle, the system comprising a plurality of propulsion battery packs and at least one electric machine connected to said plurality of propulsion battery packs, wherein said computer program product comprising computer instructions to cause one or more controllers to perform the following operations:
perform isolation measurement of the system when in operation;
if an isolation fault is detected in the system, then disconnect all propulsion battery packs;
measure isolation resistance between a plus side of each battery pack and ground and measure isolation resistance between a minus side of each battery pack and ground; and
if the measured isolation resistance in a battery pack is above a pre-determined value, re-connect that battery pack, and if the measured isolation resistance is below a pre-determined value in a battery pack, maintain that battery pack disconnected.

7. (canceled)

8. A controller for handling isolation faults in a battery operated high voltage electric system for propelling a vehicle, the high voltage electric system comprising a plurality of propulsion battery packs, each propulsion battery pack provided with contactors, each battery pack provided with means for measuring isolation resistance connected to said controller, and at least one electric machine connected to said plurality of battery packs, wherein the controller is configured to:
verify that the system is in operation;
an isolation fault in the system during operation is detected, then activate said contactors for disconnecting all propulsion battery packs
obtain information from the isolation resistance measuring means regarding the isolation resistance between a plus side of each battery pack and ground and the isolation resistance between a minus side of each battery pack and ground; and
activate the contactors of a battery pack for re-connection to the system if the obtained isolation resistance value in that battery pack is above a pre-determined value, and maintain a battery pack disconnected from the system if the obtained isolation resistance value in that battery pack is below a pre-determined value.

9. A high voltage electric system for propelling a vehicle, the system comprising:
a plurality of propulsion battery packs each battery pack comprising contactors and means for measuring isolation resistance;
at least one electric machine connected to said plurality of propulsion battery packs; and
a controller for handling isolation faults, said controller configured to:
verify that the system is in operation;
if an isolation fault in the system during operation is detected, then activate said contactors for disconnecting all propulsion battery packs;
obtain information from the isolation resistance measuring means regarding the isolation resistance between a plus side of each battery pack and ground and the isolation resistance between a minus side of each battery pack and ground; and
activate the contactors of a battery pack for re-connection to the system if the obtained isolation resistance value in that battery pack is above a pre-determined value, and maintain a battery pack disconnected from the system if the obtained isolation resistance value in that battery pack is below a pre-determined value.

10. A vehicle comprising a high voltage electric system for propelling the vehicle, the high voltage electric system comprising:
a plurality of propulsion battery packs, each battery pack comprising contactors and means for measuring isolation resistance;
at least one electric machine connected to said plurality of propulsion battery packs; and
a controller for handling isolation faults, said controller configured to:
verify that the system is in operation;
if an isolation fault in the system during operation is detected, then activate said contactors for disconnecting all propulsion battery packs;
obtain information from the isolation resistance measuring means regarding the isolation resistance between a plus side of each battery pack and ground and the isolation resistance between a minus side of each battery pack and ground; and
activate the contactors of a battery pack for re-connection to the system if the obtained isolation resistance value in that battery pack is above a pre-determined value, and maintain a battery pack disconnected from the system if the obtained isolation resistance value in that battery pack is below a pre-determined value.
